(19) United States
(12) Patent Application Publication
(10) Pub. No.: US 2026/0255766 A1
(43) Pub. Date: Aug. 27, 2026

(54) DISPLAY APPARATUS AND VEHICLE DISPLAY APPARATUS

(71) Applicant: LG Display Co., Ltd., Seoul (KR)

(72) Inventors: MiHyung Chin, Paju-si (KR); Nam Ki, Paju-si (KR)

(21) Appl. No.: 19/401,552

(22) Filed: Nov. 26, 2025

(30) Foreign Application Priority Data
Feb. 27, 2025 (KR) 10-2025-0026127

(51) Int. Cl. H10H 29/855; H10H 29/853

(52) U.S. Cl. CPC H10H 29/8552; H10H 29/853

(57) ABSTRACT

A display apparatus including a cover substrate including a transmissive area and a blocking area, a display panel overlapping the transmissive area, a light shielding layer on the blocking area, a protective film on the light shielding layer, and a vibration element on the protective film. The light shielding layer includes an opening, and the protective film and the vibration element each overlap the opening. The display apparatus may be used as a vehicle display apparatus.

### CROSS-REFERENCE TO RELATED APPLICATION

This application claims priority from and the benefit of Korean Patent Application No. 10-2025-0026127, filed on Feb. 27, 2025, which is hereby incorporated by reference for all purposes as if fully set forth herein.

### BACKGROUND

### Field

Embodiments of the invention relate generally to a display apparatus, and more particularly, to a vehicle display apparatus including a vibration element.

### Discussion of the Background

Recently, haptic technology has been developed to provide haptic feedback, or tactile feedback, corresponding to touch input when a user touches a display apparatus screen. The display devices utilizing haptic technology stimulate the human body's tactile receptors (tango-receptors), thereby enhancing the user's sense of touch and enabling them to perceive the texture of the touch.

Tactile feedback, also referred to as haptic feedback, may provide more vivid feedback to users using touch interfaces when haptic feedback is applied. The haptic feedback is a technology that allows users to feel touch, force, and movement through input devices such as keyboards, mouse, joysticks, and touch screen panels. In particular, technology related to tactile feedback that utilizes the sense of touch felt by the skin is being applied to portable electronic devices such as smart phone, electronic notebook, e-book, portable multimedia player (PMP), navigation system, mobile phone, tablet PC (personal computer), smart watch, watch phone, wearable device, and game console. In addition, displays to which haptic technology is applied may be used as displays in vehicles such as automobiles, for example.

A vibrating element or actuator may be used for haptic feedback.

The above information disclosed in this Background section is only for understanding of the background of the inventive concepts, and, therefore, it may contain information that does not constitute prior art.

### SUMMARY

Display apparatuses and vehicles including the same according to embodiments of the invention are capable of providing a display area which is not reduced even when a vibration element or actuator is disposed in the display apparatus for haptic feedback.

Additional features of the inventive concepts will be set forth in the description which follows, and in part will be apparent from the description, or may be learned by practice of the inventive concepts.

According to one or more embodiments of the invention, a display apparatus includes a cover substrate including a transmissive area and a blocking area, a display panel overlapping the transmissive area, a light shielding layer disposed on the blocking area, a protective film disposed on the light shielding layer, and a vibration element disposed on the protective film. The light shielding layer includes an opening, and each of the protective film and the vibration element overlaps the opening.

A part of the cover substrate may be exposed from the light shielding layer by the opening.

The display apparatus may further include a first adhesive layer arranged between the light blocking layer and the protective film. The first adhesive layer may contact the protective film and may contact the cover substrate in the opening.

The first adhesive layer may have light blocking property.

The first adhesive layer may have an optical density of 1.5 or more.

The protective film may have a light blocking property.

The display apparatus may further include a second adhesive layer between the protective film and the vibration element.

The light shielding layer may have two or more openings, and one protective film may be disposed on the two or more openings.

A plurality of the vibration elements may be disposed on one protective film.

A plurality of the vibration elements may be disposed on one opening.

The display apparatus may further include a sealing material contacting the first adhesive layer and the protective film.

The display apparatus may further include a light shielding film on the vibration element.

The display apparatus may further include a touch unit arranged between the cover substrate and the display panel.

The display apparatus may further include a touch sensing unit electrically connected to the touch unit, and a vibration driving unit connected to the touch sensing unit. The touch sensing unit may sense a touch applied to the touch unit to generate a touch sensing signal, and the vibration driving unit may generate a vibration driving signal based on the touch sensing signal and may provide the vibration driving signal to the vibration element.

The display apparatus may further include a fixing member for fixing the vibration element.

According to yet another embodiment of the invention, a vehicle display apparatus includes a cover substrate including a transmissive area and a blocking area, a display panel overlapping the transmissive area, a light shielding layer disposed on the blocking area, a protective film disposed on the light shielding layer, and a vibration element disposed on the protective film. The light shielding layer includes an opening, and each of the protective film and the vibration element overlaps the opening.

The display may be embedded in one of the components of the vehicle.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic perspective view of a display apparatus according to an embodiment of the invention.

FIG. 2 is a cross-sectional view taken along line I-I′ of FIG. 1 and a schematic diagram of a touch driving circuit.

FIG. 3 is a schematic diagram of the touch unit, touch sensing unit, and control unit of FIG. 2.

FIG. 4 is a plan view of a back surface of a cover substrate applied to a display apparatus according to an embodiment of the invention.

FIG. 5 is a cross-sectional view taken along line II-II′ of FIG. 4.

FIG. 6 is a cross-sectional view of a portion of a display apparatus according to another embodiment of the invention.

FIG. 7 is a plan view of a back surface of a cover substrate applied to a display apparatus according to another embodiment of the invention.

FIG. 8 is a plan view of a back surface of a cover substrate applied to a display apparatus according to another embodiment of the invention.

FIG. 9 is a cross-sectional view taken along line III-III′ of FIG. 8.

FIG. 10 is a cross-sectional view of a portion of a display apparatus according to another embodiment of the invention.

FIG. 11 and FIG. 12 are cross-sectional views of a portion of a display apparatus according to another embodiment of the invention, respectively.

FIG. 13A and FIG. 13B are plan views of the light shielding pattern formed in the opening, respectively.

FIG. 14, FIG. 15, and FIG. 16 are plan views of the back surface of a cover substrate applied to a display apparatus according to another embodiment of the invention, respectively.

FIG. 17A and FIG. 17B are schematic diagrams of a state in which a vibration element is fixed by a fixing member, respectively.

FIG. 18 is a schematic diagram of the interior of a vehicle according to another embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

The display apparatus according to an embodiment of the invention may refer to a display module including a display panel and a driving unit for driving the display panel. The display module may include a liquid crystal display module and a light emitting display module e.g., an organic light emitting display module. In addition, the display apparatus may also refer to as a complete product or a final product including a display module such as a notebook computer, a television, a computer monitor; a equipment apparatus for an automotive, or other form of a vehicle; or a set electronic apparatus, set device or set apparatus such as a mobile electronic apparatus including a smart phone or an electronic pad.

Hereinafter, embodiments of the invention will be described in detail with reference to the attached drawings. The scale of components depicted in the drawings may differ from the actual scale for convenience of explanation. Therefore, actual components are not limited to the scale depicted in the drawings.

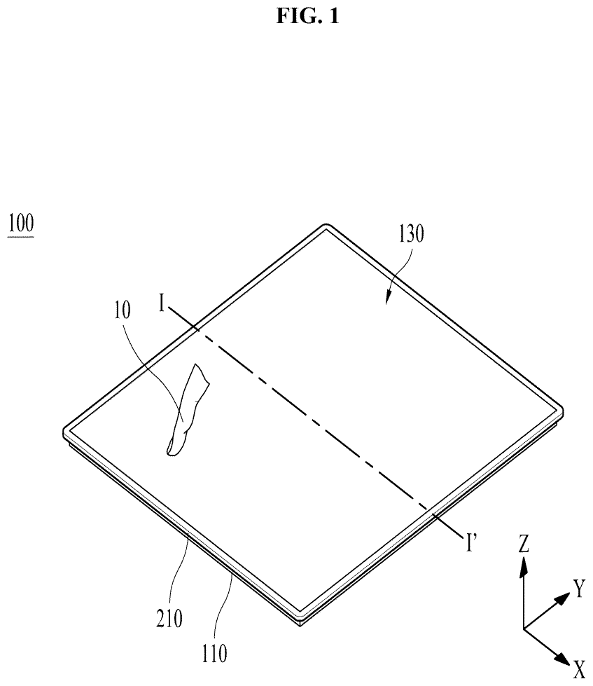

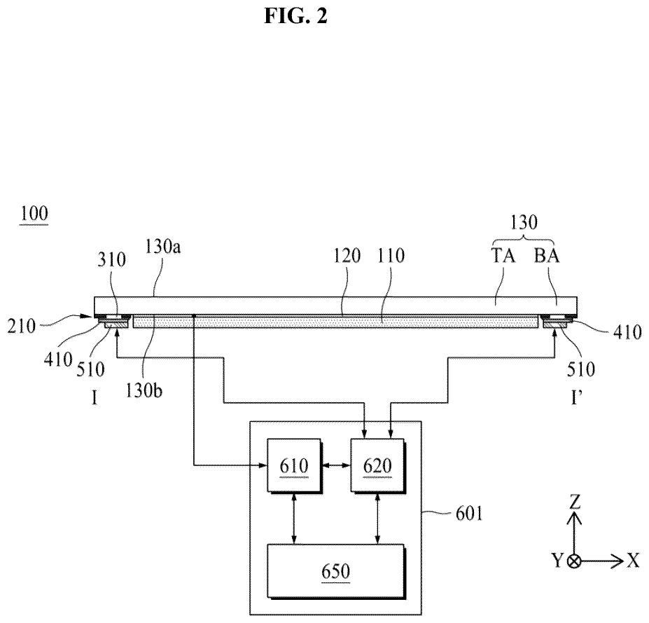

FIG. 1 is a schematic perspective view of a display apparatus 100 according to one embodiment of the invention, and FIG. 2 is a cross-sectional view taken along line I-I′ of FIG. 1 and a schematic diagram of a touch driving circuit 601.

A display apparatus 100 according to one embodiment of the invention includes a display panel 110, a touch unit 120, a cover substrate 130, a light shielding layer 210, a protective film 410, and a vibration element 510. The display apparatus 100 may further include a first adhesive layer 310 or a second adhesive layer 320 (FIG. 6).

The cover substrate 130 is the frontmost structure of the display apparatus 100 and can protect the display panel 110 and the touch unit 120 from external impact.

The cover substrate 130 may be made of, but is not limited to, transparent plastic, glass, or tempered glass. The cover substrate 130 may be referred to as, for example, a front structure, a front window, a cover window, a glass window, a cover screen, a screen cover, or window glass.

The cover substrate 130 may include a transmissive area TA and a blocking area BA. The transmissive area TA is an area that transmits light. The blocking area BA is an area that blocks light. By placing a light shielding layer 210 on the blocking area BA, the blocking area BA can block light. The transmissive area TA may be defined as an area surrounded by the blocking area BA.

The display panel 110 displays an image. The display panel 110 may include a plurality of pixels configured to display an image. The display panel 110 may include, for example, at least one of an organic light emitting display panel, a liquid crystal display panel, an electrophoretic display panel, a mini light emitting diode display panel, a micro light emitting diode display panel, an electrowetting display panel, and a quantum dot light emitting display panel. However, the display panel 110 is not limited thereto, and any panel capable of displaying an image may be the display panel 110 according to an embodiment of the invention. The display panel 110 is not limited in its shape or size.

The display panel 110 overlaps with the transmissive area TA. As the display panel 110 is disposed to overlap with the transmissive area TA of the cover substrate 130, the image displayed on the display panel 110 may be viewed from the outside through the transmissive area TA. The viewer can visually recognize the image displayed on the display panel 110 through the transmissive area TA of the cover substrate 130.

The display panel 110 may be disposed on the back surface 130b of the cover substrate 130. The cover substrate 130 includes a front surface 130a and a back surface 130b, and the back surface 130b of the cover substrate 130 refers to a surface of the cover substrate 130 that faces the display panel 110. In addition, among the surfaces of the cover substrate 130, a surface that is visible to a user is referred to as the “front surface” of the cover substrate 130. The viewer can visually recognize an image displayed on the display panel 110 through the front surface 130a of the cover substrate 130.

In addition, among the surfaces of the display panel 110, the side toward the cover substrate 130 is referred to as the “front side” of the display panel 110, and the side opposite the cover substrate 130 is referred to as the back side of the display panel 110. Referring to FIG. 1 and FIG. 2, the X-axis direction may be referred to as the horizontal direction, the Y-axis direction may be referred to as the vertical direction, and the Z-axis direction may be referred to as the thickness direction. The screen of the display apparatus 100 may be displayed in the Z-axis direction, and the Z-axis direction may be referred to as the front side. In the following embodiments, the directions of the X-axis, Y-axis, and Z-axis and the definitions of the front and back sides are the same.

The display apparatus 100 according to one embodiment of the invention may include a light shielding layer 210 on a blocking area BA, a protective film 410 on the light shielding layer 210, and a vibration element 510 on the protective film 410. The light shielding layer 210, the protective film 410, and the vibration element 510 may be disposed on the back surface 130b of the cover substrate 130. The first adhesive layer 310 may be disposed between the light shielding layer 210 and the protective film 410. By the first adhesive layer 310, the protective film 410 and the vibration element 510 may be stably fixed and attached to the light shielding layer 210.

The detailed configuration of the light shielding layer 210, protective film 410, vibration element 510, and first adhesive layer 310 will be described later.

The display apparatus 100 according to one embodiment of the invention may include a touch unit 120. The touch unit 120 senses a user touch on the display apparatus 100. For example, the touch unit 120 may be configured to sense a user touch via a touch pen or a finger 10. The touch unit 120 may be referred to by various names. The touch unit 120 may also be referred to as a “touch screen”, a “touch panel”, a “touch pad”, a “touch surface”, or the like.

The touch unit 120 may be disposed between the cover substrate 130 and the display panel 110. The touch unit 120 may be made separately from the display panel 110 or may be formed integrally with the display panel 110. The touch unit 120 may be connected to or attached to the back surface 130b of the cover substrate 130.

However, embodiments of the invention are not limited thereto, and the touch unit 120 may be disposed in various forms. For example, the touch unit 120 may be disposed within the pixel array unit of the display panel 110. In this case, the touch unit 120 may be configured as an in-cell touch panel. In addition, the touch electrode layer may become the touch unit 120, and the touch sensor layer may become the touch unit 120.

Referring to FIG. 2, the display apparatus 100 may include a touch driving circuit 601. The touch driving circuit 601 may include a touch sensing unit 610, a vibration driving unit 620, and a control unit 650.

The touch sensing unit 610 may be electrically connected to the touch unit 120. The touch sensing unit 610 senses a touch applied to the touch unit 120 and generates a touch sensing signal.

For example, when a touch electrode disposed on a touch unit 120 is touched, the corresponding input value may be sensed by the touch sensing unit 610. The touch sensing unit 610 can generate a touch sensing signal based on the touch input value and sample the touch sensing signal to generate touch sensing data. The touch sensing signal may be analog information such as a voltage signal, and the touch sensing data may be digital information converted into a digital form, but is not limited thereto.

The control unit 650 controls the touch sensing unit 610 and the vibration driving unit 620. The control unit 650 can generate a control signal for controlling the operation of the touch sensing unit 610 and the vibration driving unit 620, and transmit the generated control signal to each of the touch sensing unit 610 and the vibration driving unit 620. In addition, the control unit 650 can perform a touch algorithm using the touch sensing signal or touch sensing data received from the touch sensing unit 610, and determine the presence or absence of a touch input and the touch position. The control unit 650 can electrically connect the vibration element 510 and the vibration driving unit 620.

The vibration driving unit 620 is electrically connected to the vibration element 510 and can apply a vibration driving signal to the vibration element 510 to vibrate the vibration element 510. The vibration driving unit 620 can generate a vibration driving signal based on a touch sensing signal and provide the vibration driving signal to the vibration element 510. The vibration driving unit 620 can generate a vibration driving signal under the control of the control unit 650 and provide the vibration driving signal to the vibration element 510. In addition to a touch operation, the vibration driving unit 620 can generate a vibration driving signal for system notifications (e.g., low battery, low memory, security notification, or the like.), incoming messages or phone calls, program notifications, or the like., but is not limited thereto.

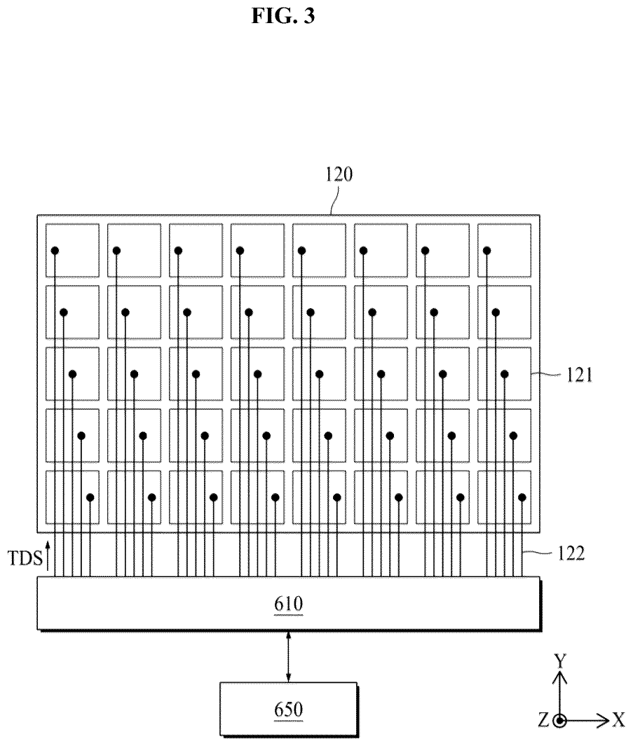

FIG. 3 is a schematic diagram of the touch unit 120, touch sensing unit 610, and control unit 650 of FIG. 2. FIG. 3 illustrates a touch panel with the touch unit 120.

Referring to FIG. 3, the touch unit 120 may include a plurality of touch electrodes 121 and a plurality of touch lines 122 for electrically connecting the plurality of touch electrodes 121 to the touch sensing unit 610. The touch sensor may be formed by the touch electrode 121 and the touch line 122.

The touch sensing unit 610 can supply a touch driving signal TDS to all or part of a plurality of touch electrodes 121, sense all or part of the plurality of touch electrodes 121, generate a touch sensing signal or touch sensing data, and provide the generated touch sensing signal or touch sensing data to the control unit 650.

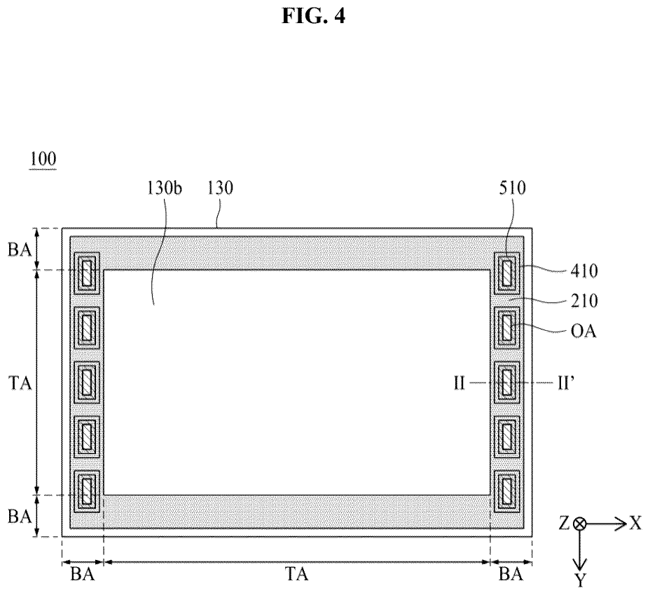

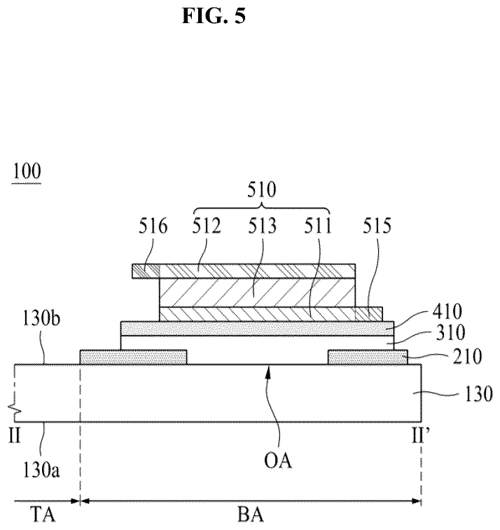

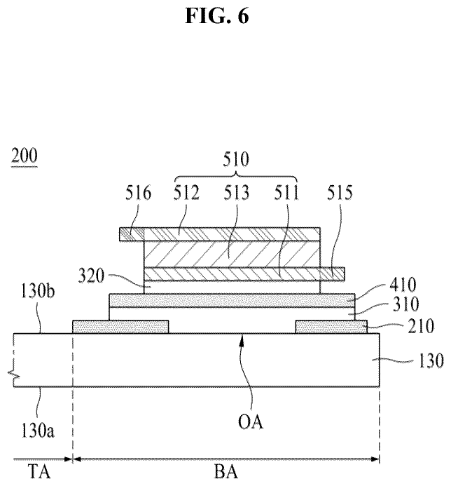

FIG. 4 is a plan view of the back surface 130b of the cover substrate 130 applied to the display apparatus 100 according to one embodiment of the invention, and FIG. 5 is a cross-sectional view taken along line II-II′ of FIG. 4.

Referring to FIG. 4 and FIG. 5, a light shielding layer 210 is disposed on the back surface 130b of the cover substrate 130. The light shielding layer 210 may be disposed on the blocking area BA of the cover substrate 130. The light shielding layer 210 blocks light incident on the cover substrate 130 from passing through the blocking area BA.

A transmissive area TA and a blocking area BA may be defined by the light shielding layer 210. The area surrounded by the light shielding layer 210 may become the transmissive area TA of the substrate 130, and the area where the light shielding layer 210 is disposed may become the blocking area BA of the substrate 130.

The light shielding layer 210 has a light blocking property. The light shielding layer 210 may be formed of a light blocking material. The light shielding layer 210 can absorb light.

For example, the light shielding layer 210 may be formed of the same material as the black matrix that serves to distinguish each color area in a color filter. However, the material for forming the light shielding layer 210 is not limited thereto, and any material capable of blocking light may be used as the material for forming the light shielding layer 210 without limitation.

The light shielding layer 210 may contact the cover substrate 130. The light shielding layer 210 is disposed in the blocking area BA of the cover substrate 130. The light shielding layer 210 may be formed on the blocking area BA by coating, but is not limited thereto. The light shielding layer 210 may be formed on the blocking area BA by deposition, or a film having light blocking property may be attached to the blocking area BA to form the light shielding layer 210.

The light shielding layer 210 includes an opening OA. A part of the cover substrate 130 may be exposed from the light shielding layer 210 through the opening OA. After the light shielding layer 210 is formed, a portion of the material constituting the light shielding layer 210 may be removed to form the opening OA. A portion of the cover substrate 130 is exposed from the light shielding layer 210 through the opening OA. The light shielding layer 210 may have two or more openings OA.

Although the opening OA is depicted as having a rectangular shape in FIG. 4, the shape of the opening OA is not limited thereto. The opening OA may have various planar shapes other than a rectangular shape. For example, the opening OA may have a planar shape such as a circle, an ellipse, or a polygon.

Referring to FIG. 4 and FIG. 5, a protective film 410 may be disposed on a light shielding layer 210, and a vibration element 510 may be disposed on the protective film 410. In addition, a first adhesive layer 310 may be disposed between the light shielding layer 210 and the protective film 410. Accordingly, the protective film 410 may cover the opening. In addition, the protective film 410 may cover a portion of the light shielding layer 210.

The first adhesive layer 310 serves to fix the protective film 410 and the vibration element 510 onto the cover substrate 130. The first adhesive layer 310 may be disposed on the light shielding layer 210. At least a portion of the first adhesive layer 310 may be disposed in the opening OA of the light shielding layer 210.

The first adhesive layer 310 may have a light blocking property. Since the first adhesive layer 310 has a light blocking property, even if an opening OA is formed in the light shielding layer 210, light transmission through the opening OA may be blocked. Even if a vibration element 510 is disposed on an opening OA where a light blocking material is not disposed, the vibration element 510 may not be visible to the user.

The first adhesive layer 310 may include an adhesive polymer. The adhesive polymer may have adhesive and a tacky property. Therefore, the adhesive polymer may also be referred to as a “tacky polymer”. Examples of adhesive polymers include acrylic resins, urethane resins, and epoxy resins. However, the adhesive polymer is not limited thereto, and other adhesive polymers known in the art may be applied to the first adhesive layer 310.

The first adhesive layer 310 may include a light blocking additive dispersed in an adhesive polymer. Any material capable of blocking light may be used as the light blocking additive without limitation.

For example, carbon black may be used as a light blocking additive. Carbon black may be considered a type of black pigment. However, the light blocking additive is not limited to this, and at least one of a black pigment and a black dye may be used as a light blocking additive. In addition to carbon black, other colored particles with a light blocking effect can also be used as a light blocking additive. For example, silicon oxide particles, titanium oxide particles, aluminum oxide, or the like. may be used as a light blocking additive. In addition to pigments or dyes, UV diffusers such as metal nanoparticles and UV diffuser beads can also be used as additives.

The first adhesive layer 310 may have an optical density of 1.5 or more. The optical density is a value indicating the degree to which the intensity of light is weakened when passing through an object. The optical density is defined as a logarithmic value of the ratio of the intensity of light incident on an object to the intensity of light transmitted through the object. When the intensity of light incident on an object is I₀ and the intensity of light after passing through the object is I₁, the optical density A may be obtained by Equation 1.

$$An optical density = log {I}_{0} / {I}_{1} \qquad [ Equation 1 ]$$

An optical density of 1.5 or more corresponds to a light transmittance of 3.16% or less. When the first adhesive layer 310 has an optical density of 1.5 or more, even if light is incident through the opening OA of the light shielding layer 210, light transmission may be suppressed by the first adhesive layer 310.

In detail, the first adhesive layer 310 may have an optical density of 1.5 to 3.5, may have an optical density of 1.5 to 2.5, may have an optical density of 1.5 to 2.0, or may have an optical density of 2.0 to 2.5.

The protective film 410 may be disposed on the first adhesive layer 310. The protective film 410 may contact the first adhesive layer 310. The protective film 410 may be disposed on the light shielding layer 210 while being adhered to the first adhesive layer 310.

The protective film 410 has a light blocking property. Therefore, light may be blocked by the protective film 410. The light incident through the opening OA of the light shielding layer 210 may be blocked by the protective film 410.

The protective film 410 overlaps with the opening OA of the light shielding layer 210. Referring to FIG. 4, the protective film 410 covers the entire opening OA of the light shielding layer 210 in a plan view. The protective film 410 has a larger area than the opening OA and can cover the entire opening OA. As a result, light incident through the opening OA may be blocked by the protective film 410. In a plan view, a portion of the protective film 410 can extend outside the opening OA and overlap with the light shielding layer 210.

There is no particular limitation on the material of the protective film 410. The film or sheet having light blocking property may be used as the protective film 410 of the display apparatus 100 according to an embodiment of the invention.

For example, the protective film 410 may include a polymer film resin and a light absorber dispersed in the polymer film resin.

The polymer film resin may include, for example, at least one of polyethylene terephthalate (PET), polyimide (PI), polyamide (PA), polycarbonate (PC), polyacrylic, and polyurethane.

The light absorber may include a black pigment or black dye. The light absorber may include, for example, at least one of carbon black, silicon oxide particles, titanium oxide particles, aluminum oxide particles, and metal nanoparticles (Nano Metal).

The vibration element 510 is disposed on the protective film 410. The vibration element 510 may be fixed on the protective film 410. The vibration element 510 can also be formed integrally with the protective film 410.

Referring to FIG. 4 and FIG. 5, the protective film 410 and the vibration element 510 can overlap with the opening OA of the light shielding layer 210, respectively. Accordingly, the first adhesive layer 310 may contact the protective film 410 and, at the same time, may contact the cover substrate 130 at the opening OA. The first adhesive layer 310 may contact both the protective film 410 and the cover substrate 130 on the opening OA. When the vibration element 510 is stably fixed to the protective film 410, and the first adhesive layer 310 contacts the protective film 410 and, at the same time, with the cover substrate 130, the vibration element 510 may be stably attached to the cover substrate 130 via the first adhesive layer 310.

When at least a portion of the first adhesive layer 310 directly contacts the cover substrate 130, the first adhesive layer 310 may be more strongly adhered to the cover substrate 130 compared to when the first adhesive layer 310 is in direct contact only with the light shielding layer 210. As a result, the vibration element 510 may be strongly attached to the cover substrate 130.

In addition, when the first adhesive layer 310 directly contacts the cover substrate 130, the phenomenon of the light shielding layer 210 being peeled off or separated from the cover substrate 130 due to the vibration of the vibration element 510 may be prevented or reduced. As a result, the vibration element 510 may be stably fixed on the cover substrate 130 without the light shielding layer 210 being lifted or peeled off.

Although the first adhesive layer 310 contacts the light shielding layer 210, the adhesive force for fixing the protective film 410 and the vibration element 510 to the cover substrate 130 mainly occurs at the bonding portion between the first adhesive layer 310 and the cover substrate 130. Therefore, even if the vibration element 510 vibrates, the phenomenon of the light shielding layer 210 being peeled off or separated from the cover substrate 130 may be suppressed or prevented.

The vibration element 510 may be disposed on an area covered by at least one of the light shielding layer 210 and the protective film 410. Referring to FIG. 4, the vibration element 510 may be disposed within an area where the protective film 410 is disposed in a planar view. As a result, the vibration element 510 may not be visible to the user. Since the protective film 410 has light blocking property, even if an opening OA is formed in the light shielding layer 210, the vibration element 510 may be prevented or reduced from being visible to the user through the opening OA.

As a vibration element 510, for example, an actuator or a piezoelectric element may be used, but the vibration element 510 is not limited thereto.

Referring to FIG. 5, the vibration element 510 may include a first electrode 511, a piezoelectric layer 513 on the first electrode 511, and a second electrode 512 on the piezoelectric layer 513.

The first electrode 511 and the second electrode 512 are spaced apart from each other with the piezoelectric layer 513 interposed therebetween, and at least a portion of the first electrode 511 and the second electrode 512 may be formed of a metal material having low resistance and excellent heat dissipation property. Alternatively, the first electrode 511 and the second electrode 512 may include a transparent conductive oxide or a conductive polymer.

The first electrode 511 and the second electrode 512 may each include at least one of a metal including silver (Ag), magnesium (Mg), aluminum (Al), copper (Cu), platinum (Pt), palladium (Pd), gold (Au), nickel (Ni), neodymium (Nd), iridium (Ir), and chromium (Cr), a transparent conductive oxide including ITO (InSnO), IZO (InZnO), IZTO (InZnSnO), ZnO, and In₂O₃, and a conductive polymer including polyaniline, polypyrrole, and polythiophene.

The piezoelectric layer 513 includes a piezoelectric material. The piezoelectric material can generate vibrations due to an electric field. When pressure or a torsion phenomenon is applied to the crystal structure of the piezoelectric material by an external force, a potential difference may be generated in the piezoelectric material due to dielectric polarization resulting from a change in the relative positions of positive (+) and negative (−) ions. Conversely, when an electric field is applied to the piezoelectric material, the piezoelectric material can generate vibrations.

Referring to FIG. 5, the vibration element 510 may be electrically connected to a first connecting wire 515 and a second connecting wire 516. The first connecting wire 515 may be electrically connected to a first electrode 511, and the second connecting wire 516 may be electrically connected to a second electrode 512. The first connecting wire 515 and the second connecting wire 516 may be electrically connected to an external terminal, an external pad, or a driving circuit, respectively.

The first connecting wire 515 may be formed integrally with the first electrode 511, and the second connecting wire 516 may be formed integrally with the second electrode 512. Although not shown in the drawing, the first connecting wire and the second connecting wire may be formed separately from the first electrode and the second electrode, respectively. In addition, the first electrode and the second electrode may have a structure in which they are laminated in multiple layers, and a plurality of piezoelectric layers may be disposed between the first electrode and the second electrode.

The first electrode 511 and the second electrode 512 may be electrically connected to the vibration driving unit 620 through the first connecting wire 515 and the second connecting wire 516, respectively, and the vibration element 510 can vibrate in response to a touch applied to the touch unit 120.

For example, the first connecting wire 515 may provide a vibration driving signal to the vibration element 510. The vibration driving signal generated from the vibration driving unit 620 may be input to the first electrode 511 of the vibration element 510 through the first connecting wire 515. A plurality of vibration elements 510 can each be independently connected to the first connecting wire 515.

The second connecting wire 516 is electrically connected to the second electrode 512 and may apply a common voltage to the vibration element 510. The second electrode 512 may also be electrically connected to a ground terminal. Additionally, a plurality of vibration elements 510 may be electrically connected to a single second connecting wire 516.

FIG. 6 is a cross-sectional view of a portion of a display apparatus 200 according to another embodiment of the invention. In detail, FIG. 6 illustrates a cross-section corresponding to FIG. 5, and the configuration illustrated in FIG. 6 differs from the configuration illustrated in FIG. 5 in that it further includes a second adhesive layer 320. Hereinafter, descriptions of components already described will be omitted to avoid duplication.

Referring to FIG. 6, the display apparatus 200 includes a second adhesive layer 320 between a protective film 410 and a vibration element 510. The second adhesive layer 320 serves to secure the protective film 410 to the vibration element 510.

The second adhesive layer 320 may include an adhesive polymer. Examples of the adhesive polymer include acrylic resins, urethane resins, and epoxy resins. However, the adhesive polymer is not limited thereto, and other adhesive polymers known in the art may be applied to the second adhesive layer 320.

The second adhesive layer 320 may include an additive dispersed in the adhesive polymer. There are no specific limitations on the type of additive included in the second adhesive layer 320. For example, additives for enhancing adhesive strength and additives for preventing or reducing static electricity generation may be used as additives.

The vibration element 510 may be stably fixed to the protective film 410 by the second adhesive layer 320, and the vibration element 510 may be prevented or reduced from being detached from the protective film 410.

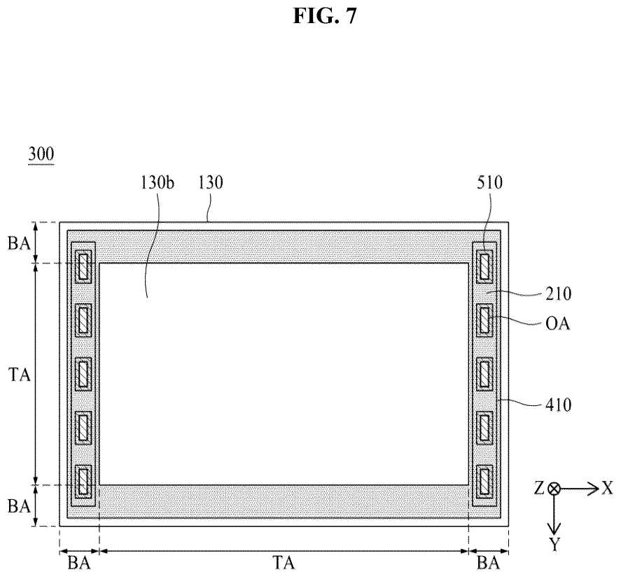

FIG. 7 is a plan view of the back surface 130b of a cover substrate 130 applied to a display apparatus 300 according to another embodiment of the invention.

Referring to FIG. 7, one protective film 410 may be disposed on two or more openings OA. In this case, one protective film 410 may extend in one direction to cover a plurality of adjacently disposed openings OA.

According to another embodiment of the invention, when one protective film 410 is configured to cover a plurality of openings OA, the process of disposing the protective film 410 may be simplified, and the placement efficiency of the protective film 410 may be improved.

Additionally, a plurality of vibration elements 510 may be disposed on the single protective film 410. When a plurality of vibration elements 510 are disposed on the single protective film 410, the efficiency of the work of disposing the vibration elements 510 is improved, and the manufacturing cost of the display apparatus 300 may be reduced.

Even if a plurality of vibration elements 510 are arranged on the single protective film 410, each of the plurality of vibration elements 510 may be disposed to overlap with an opening OA of the light shielding layer 210. In this case, the vibration of the vibration element 510 may be efficiently transmitted to the cover substrate 130.

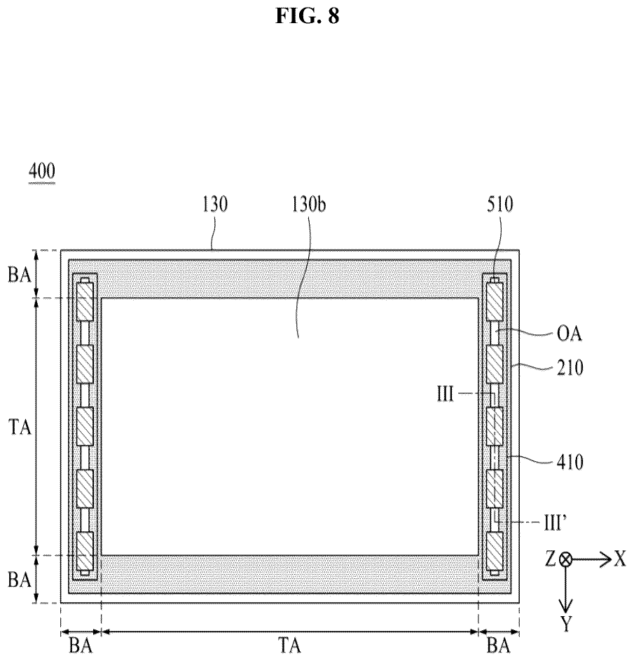

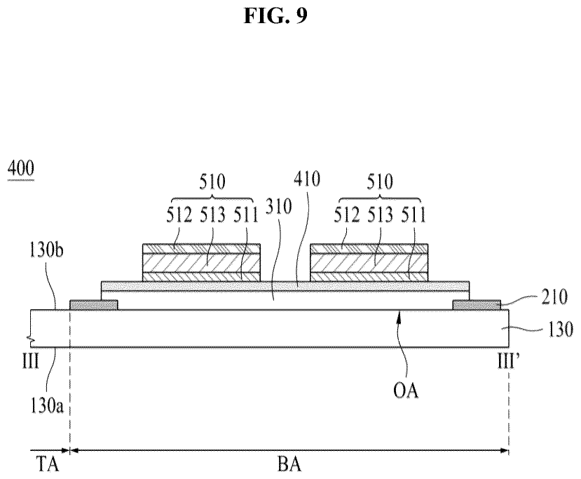

FIG. 8 is a plan view of the back surface 130b of a cover substrate applied to a display apparatus 400 according to another embodiment of the invention, and FIG. 9 is a cross-sectional view taken along line III-III′ of FIG. 8.

Referring to FIG. 8 and FIG. 9, a plurality of vibration elements 510 may be disposed on one opening OA.

In FIG. 8, the opening OA may be formed long along one side of the cover substrate 130. The protective film 410 may cover the entire opening OA in a planar view. The first adhesive layer 310 is disposed between the opening OA and the protective film 410. The first adhesive layer 310 may extend over the entire opening OA and outside of the opening OA and be disposed on the light shielding layer 210.

As illustrated in FIG. 8, when a plurality of vibration elements 510 are disposed on one opening OA and one protective film 410, the efficiency of the work of disposing the vibration elements 510 is improved, so that the manufacturing cost of the display apparatus 300 may be reduced.

As illustrated in FIG. 9, when the first adhesive layer 310 is disposed in the opening OA formed long along one side of the cover substrate 130, the contact area between the first adhesive layer 310 and the cover substrate 130 can increase. Accordingly, the bonding strength by the first adhesive layer 310 increases, and the protective film 410 and the vibration element 510 may be stably attached to the cover substrate 130 via the first adhesive layer 310. In addition, since the area where the first adhesive layer 310 directly contacts the cover substrate 130 is large and the vibration element 510 may be strongly attached to the cover substrate 130, the vibration of the vibration element 510 may be efficiently transmitted to the cover substrate 130.

Referring to FIG. 8 and FIG. 9, the vibration element 510 may not be disposed on a portion of the opening OA and the first adhesive layer 310. Even if the vibration element 510 is not disposed on the opening OA, light transmission through the opening OA may be blocked by the first adhesive layer 310 and the protective film 410.

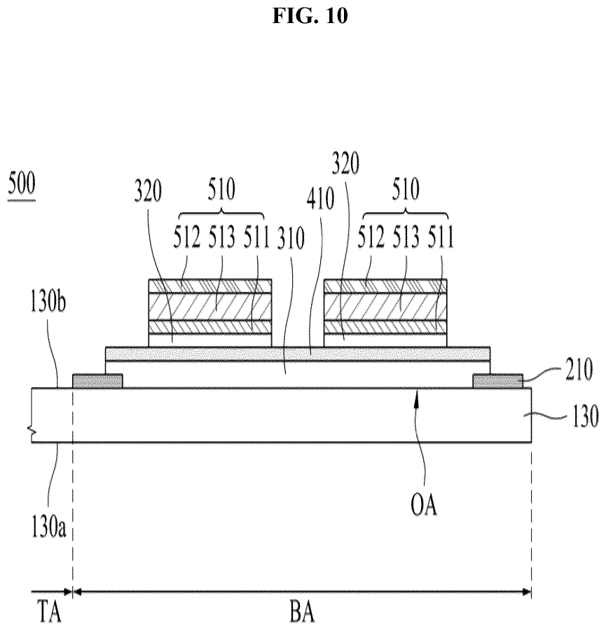

FIG. 10 is a cross-sectional view of a portion of a display apparatus 500 according to another embodiment of the invention. FIG. 10 shows a cross-section at a position corresponding to FIG. 9, and the configuration shown in FIG. 10 differs from the configuration shown in FIG. 9 in that it further includes a second adhesive layer 320.

Referring to FIG. 10, a second adhesive layer 320 may be disposed between the protective film 410 and the vibration element 510. The second adhesive layer 320 serves to secure the protective film 410 to the vibration element 510.

The vibration element 510 may be stably fixed to the protective film 410 by the second adhesive layer 320, and the vibration element 510 may be prevented or reduced from being detached from the protective film 410. Since the second adhesive layer 320 has already been described, a detailed description thereof is omitted.

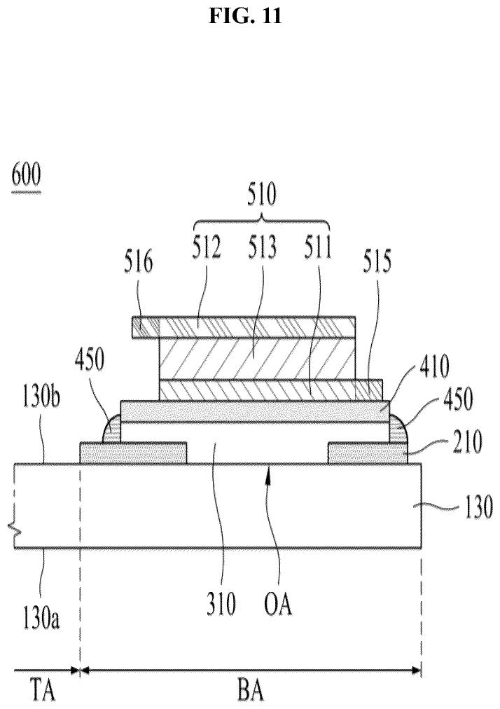

FIG. 11 is a cross-sectional view of a portion of a display apparatus 600 according to another embodiment of the invention. FIG. 11 illustrates a cross-section at a location corresponding to FIG. 5, and the configuration illustrated in FIG. 11 differs from the configuration illustrated in FIG. 5 in that it further includes a sealing material 450.

Referring to FIG. 11, the display apparatus 600 may include a sealing material 450 contacting the first adhesive layer 310 and the protective film 410. The sealing material 450 may improve the attachment stability of the first adhesive layer 310 and the protective film 410, thereby improving the fixing stability of the vibration element 510.

The sealing material 450 may contact the side surface of the first adhesive layer 310 and the side surface of the protective film 410. In addition, the sealing material 450 may contact the light shielding layer 210. The sealing material 450 may contact the upper surface of the light shielding layer 210.

By applying an uncured sealing material 450 to the side of the first adhesive layer 310, the side of the protective film 410, and the upper surface of the light shielding layer 210 and then curing it, the adhesion stability of the first adhesive layer 310 and the protective film 410 may be improved.

The sealing material 450 may include a curable resin and a light blocking additive dispersed in the curable resin. The light blocking additive may include, for example, at least one of carbon black, silicon oxide particles, titanium oxide particles, aluminum oxide particles, and metal nanoparticles (Nano Metal). However, the sealing material 450 is not limited thereto, and any known sealing material may be used as the sealing material 450 of the display apparatus 600.

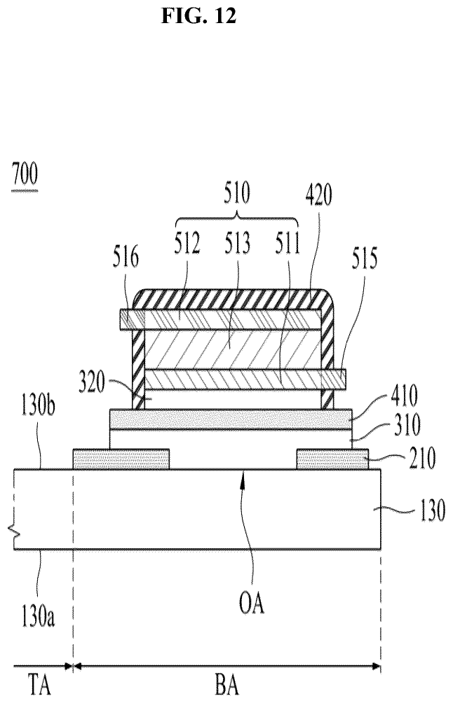

FIG. 12 is a cross-sectional view of a portion of a display apparatus 700 according to another embodiment of the invention. FIG. 12 illustrates a cross-section at a location corresponding to FIG. 5, and the configuration illustrated in FIG. 12 differs from the configuration illustrated in FIG. 5 in that it further includes a second adhesive layer 320 and a light shielding film 420.

Referring to FIG. 12, the display apparatus 700 may further include a light shielding film 420 on the vibration element 510. The light shielding film 420 protects the vibration element 510. The light shielding film 420 may be disposed on the upper surface of the vibration element 510 and may also be disposed on the side of the vibration element 510. The light shielding film 420 blocks light, thereby preventing or reducing the vibration element 510 from being unnecessarily visible to the outside.

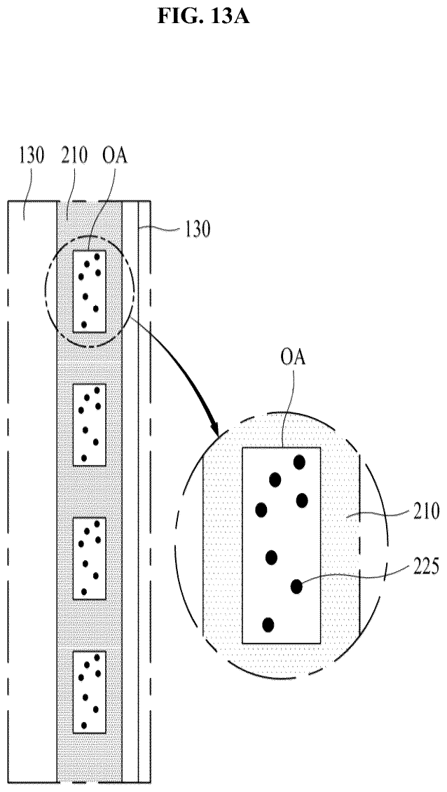

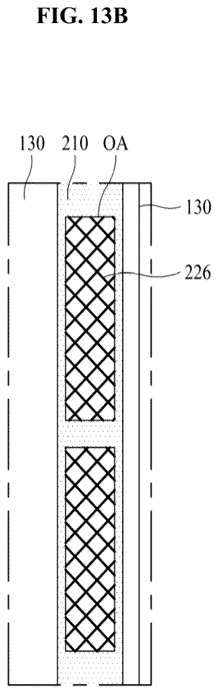

FIG. 13A and FIG. 13B are plan views of the light shielding patterns 225, 226 formed in the opening OA, respectively.

Referring to FIG. 13A and FIG. 13B, a light shielding pattern 225, 226 may be disposed in the opening OA of the light shielding layer 210. The light shielding pattern 225, 226 may be made of the same material as the material forming the light shielding layer 210. However, the light shielding pattern 225, 226 is not limited thereto, and the light shielding pattern 225, 226 may be made of a different material from the material forming the light shielding layer 210.

During the process of forming the opening OA, a portion of the material forming the light shielding layer 210 may remain without being removed, thereby forming a light shielding pattern 225, 226. Alternatively, the light shielding pattern 225, 226 may be formed in a separate process after the opening OA is formed. When the light shielding pattern 225, 226 is disposed in the opening OA, light blocking efficiency may be improved.

There is no particular limitation on the shape of the light shielding pattern 225, 226. As illustrated in FIG. 13A, the light shielding pattern 225 may have a dot-shaped plane. Referring to FIG. 13B, the light shielding pattern 226 may have a line-shaped plane. The light shielding pattern 226 may also have a grid-shaped plane formed by intersecting lines.

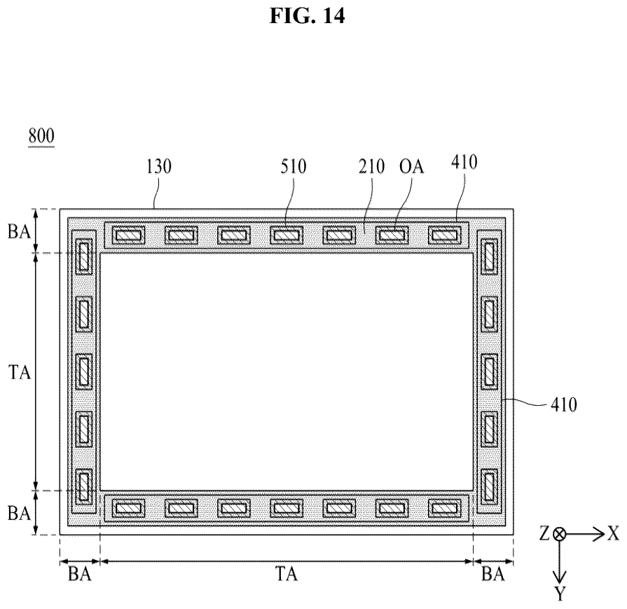

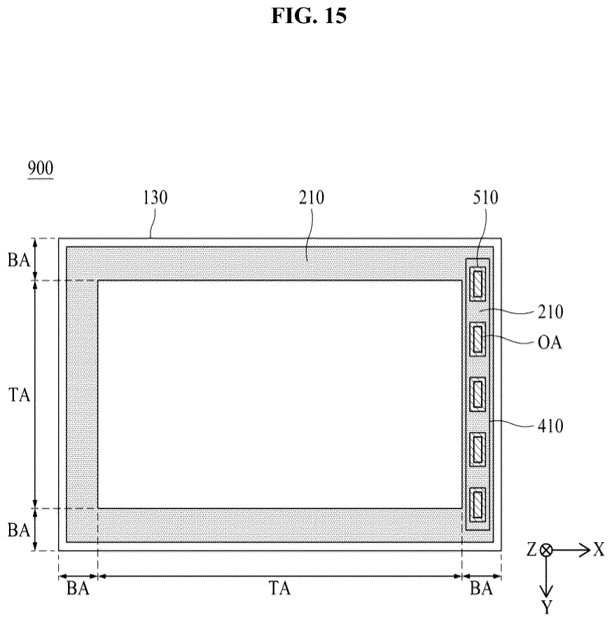

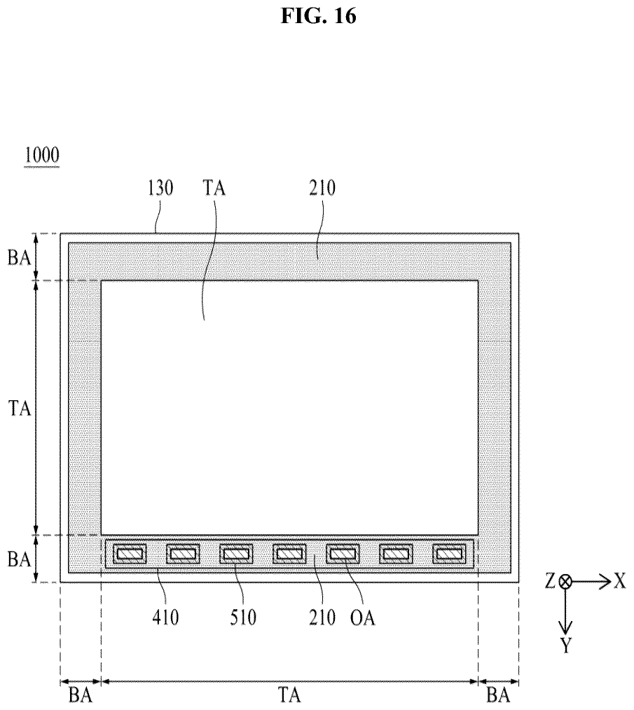

FIG. 14 to FIG. 16 are plan views of the back surface 130b of the cover substrate applied to the display apparatus 800, 900, 1000 according to another embodiment of the invention, respectively. In each of the display apparatuses 800, 900, 1000 illustrated in FIG. 14 to FIG. 16, a vibration element 510 is disposed on the cover substrate 130, and the laminated structure for the state in which the vibration element 510 is disposed is not limited by FIG. 14 to FIG. 16. The vibration element 510 may be disposed in a laminated structure as illustrated in any one of FIGS. 5, 6, 9, 10, 11 and 12, for example.

In the display apparatus 800 of FIG. 14, a light shielding layer 210 may be disposed to surround a transmissive area TA, and a plurality of openings OA may be disposed to surround the transmissive area TA. Referring to FIG. 14, a plurality of openings OA may be arranged along four sides constituting a cover substrate 130.

The protective film 410 is disposed on the opening OA of the light shielding layer 210, and the vibration element 510 is disposed on the protective film 410. The protective film 410 may be attached to the opening OA by a first adhesive layer 310. The first adhesive layer 310 may be in direct contact with the cover substrate 130 at the opening OA.

The vibration element 510 may be disposed to overlap with the opening OA. Referring to FIG. 14, a plurality of vibration elements 510 may be disposed to surround the transmissive area TA. The vibration elements 510 may be disposed on the light shielding layer 210 along the four sides constituting the cover substrate 130.

Referring to FIG. 15 and FIG. 16, the vibration element 510 may be disposed only on one edge of the cover substrate 130. The light shielding layer 210 may be disposed on the back surface 130b of the cover substrate 130 to surround the transmissive area TA, and the vibration element 510 may be disposed on the light shielding layer 210 at one edge of the cover substrate 130. The light shielding layer 210 includes the plurality of openings OA formed on one side of the cover substrate 130, and the plurality of vibration elements 510 may be disposed on the plurality of openings OA.

In the display apparatus 900 of FIG. 15, a configuration in which a plurality of vibration elements 510 are disposed along the vertical direction (Y-axis direction) of the drawing is exemplified. In the display apparatus 1000 of FIG. 16, a plurality of vibration elements 510 may be disposed along the horizontal direction (X-axis direction) of the drawing. However, the arrangement of the vibration elements 510 is not limited thereto, and the vibration elements 510 may be disposed in various forms as needed.

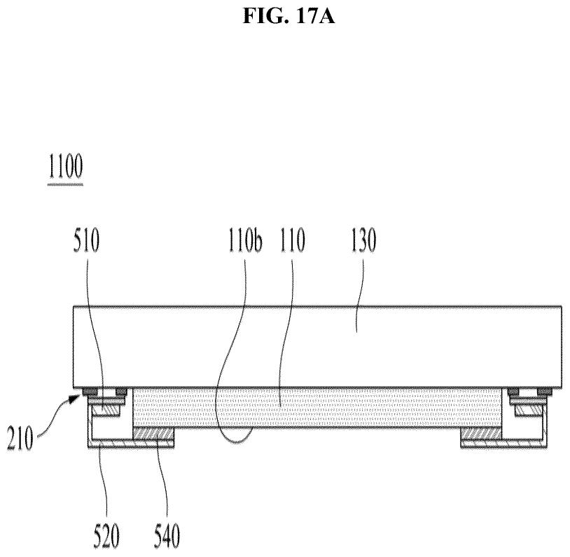

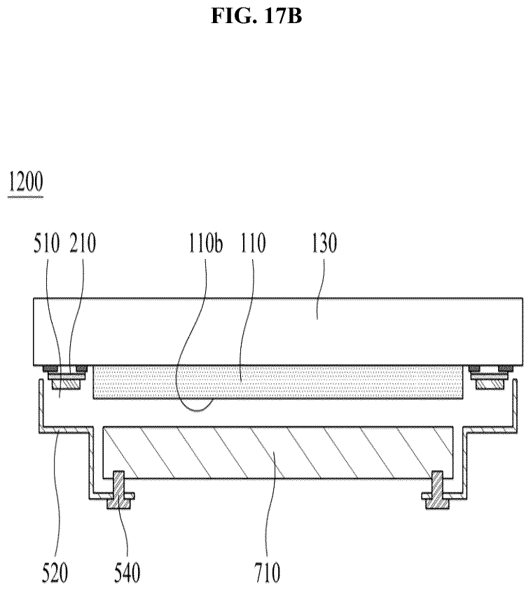

FIG. 17A and FIG. 17B are schematic diagrams of a state in which a vibration element 510 is fixed by a fixing member 520, respectively.

Referring to FIG. 17A, a display apparatus 1100 may include a fixing member 520, and one end of the fixing member 520 may be fixed to the display panel 110. The flexible member that may be deformed may be used as the fixing member 520, or a hard member that is not easily deformed may be used.

The fixing member 520 may be fixed to the display panel 110 by a fastening means 540. As the fastening means 540, for example, there is a double-sided tape. In detail, when a flexible member is used as the fixing member 520, a double-sided tape may be used as the fastening means 540. The fixing member 520 may be fixed to the back surface 110b of the display panel 110 by the fastening means 540.

The other end of the fixing member 520 may be connected to the vibration element 510. As a result, the vibration element 510 may be stably maintained in a fixed state by the adhesive layer 310 and the fixing member 520.

Referring to FIG. 17B, the display apparatus 1200 may further include a backlight unit 710. The backlight unit 710 may overlap the display panel 110. The backlight unit 710 may be disposed on the back surface 110b of the display panel 110.

In the display apparatus 1200 of FIG. 17B, one end of the fixing member 520 may be fixed to the backlight unit 710. The fixing member 520 may be fixed to the backlight unit 710 by a fastening means 540. Examples of the fastening means 540 include double-sided tape, screws, bolts, or the like.

When a hard member is used as the fixing member 520, a screw or bolt may be used as the fastening means 540. FIG. 17B illustrates an example configuration in which a screw or bolt is used as the fastening means 540.

The display apparatus according to embodiments of the invention including a vibration element 510 may be used as a display apparatus for a mobile electronic device such as a mobile phone, a smart phone, a smart watch, a tablet PC, or a watch phone, a smart television, an electronic blackboard, a transparent display apparatus, an interactive digital signage, a laptop, a monitor, or a refrigerator, but embodiments of the invention are not limited thereto.

In addition, the display apparatus including the vibration element 510 may be applied to a vehicle, such as an automobile. For example, the display apparatus including the vibration element 510 may be implemented as a user interface device such as a central control panel or a user display of the vehicle. Another embodiment of the invention provides a vehicle including the display apparatus 100, 200, 300, 400, 500, 600, 700, 800, 900, 1000, 1100, 1200 described above.

Another embodiment of the invention provides a vehicle display apparatus.

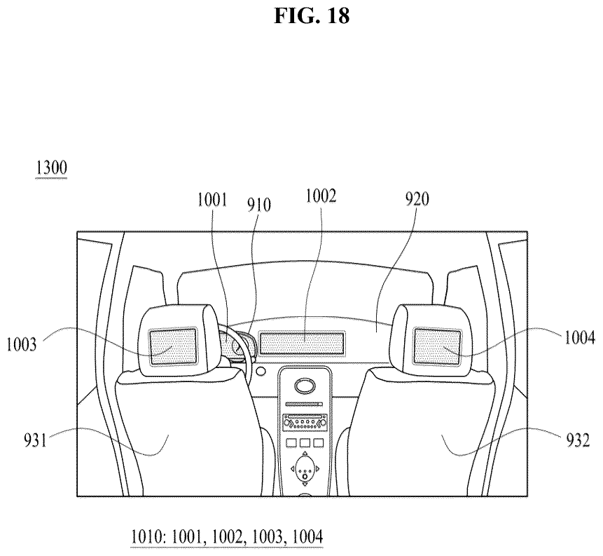

FIG. 18 is a schematic diagram of the interior of a vehicle 1300 according to another embodiment of the invention. Referring to FIG. 18, the vehicle 1300 may include an instrument panel module 910, a dashboard 920, a driver seat 931, a passenger seat 932, and a vehicle display apparatus 1010.

The vehicle display apparatus 1010 may include the display apparatus 100, 200, 300, 400, 500, 600, 700, 800, 900, 1000, 1100, 1200 described above. The vehicle display apparatus 1010 includes a cover substrate 130 including a transmissive area TA and a blocking area BA, a display panel 110 overlapping the transmissive area TA, a light shielding layer 210 on the blocking area BA, a protective film 410 on the light shielding layer 210, and a vibration element 510 on the protective film 410. The light shielding layer 210 includes an opening OA, and each of the protective film 410 and the vibration element 510 overlaps the opening OA. The display panel 110, the light shielding layer 210, the protective film 410, and the vibration element 510 may be designed to be embedded in one of the components of the vehicle 1300.

Since the cover substrate 130, display panel 110, light shielding layer 210, protective film 410, and vibration element 510 have already been described, detailed descriptions thereof are omitted.

The vehicle display apparatus 1010 may further include a first adhesive layer 310 between the light shielding layer 210 and the protective film 410. The vehicle display apparatus 1010 may further include a second adhesive layer 320 between the protective film 410 and the vibration element 510. In addition, the vehicle display apparatus 1010 may further include a touch unit 120 between the cover substrate 130 and the display panel 110. Since the first adhesive layer 310, the second adhesive layer 320, and the touch unit 120 have already been described, a detailed description thereof will be omitted.

Referring to FIG. 18, the vehicle display apparatus 1010 may include at least one of a first display 1001, a second display 1002, a third display 1003, and a fourth display 1004. As the first display 1001, the second display 1002, the third display 1003, and the fourth display 1004, the display apparatuses 100, 200, 300, 400, 500, 600, 700, 800, 900, 1000, 1100, 1200 described above may be applied. Since the display apparatuses 100, 200, 300, 400, 500, 600, 700, 800, 900, 1000, 1100, 1200 have already been described, detailed descriptions of each of the first display 1001, the second display 1002, the third display 1003, and the fourth display 1004 are omitted.

The instrument panel module 910 may include a first display 1001. The first display 1001 may be referred to as “an instrument panel display”. The first display 1001 may provide the driver with driving-related information, such as speed, fuel level, and engine RPM. The first display 1001 may display an image corresponding to information provided from the host system on a display panel.

When a driver or passenger touches the first display 1001, the vibration of the vibration element 510 may be transmitted to the driver or passenger.

The dashboard 920 may extend from the front of the driver seat 931 to the front of the passenger seat 932, and a second display 1002 may be disposed on the dashboard 920.

The second display 1002 is connected to at least one of an audio system, an air conditioning system, a multimedia system, and a navigation system, and can display information provided from at least one of the audio system, the air conditioning system, the multimedia system, and the navigation system. In addition, the second display 1002 can transmit and receive image information or audio information to and from a passenger's electronic device via wired or wireless communication, and can display the received image information.

When the driver or passenger touches the second display 1002, the vibration of the vibration element 510 may be transmitted to the driver or passenger.

A third display 1003 may be disposed on the driver seat 931, and a fourth display 1004 may be disposed on the passenger seat 932. At least one of the third display 1003 and the fourth display 1004 may be omitted.

The third display 1003 and the fourth display 1004 can each display information provided from at least one of an audio system, an air conditioning system, a multimedia system, and a navigation system, and can transmit and receive image information or audio information to and from a passenger's electronic device via wired or wireless communication and display the received image information.

When a passenger touches the third display 1003 or the fourth display 1004, the vibration of the vibration element 510 may be transmitted to the user (or driver).

According to one embodiment of the invention, since a vibration element or actuator is disposed on the light shielding layer for haptic feedback, the display area of the display apparatus may not be reduced. According to one embodiment of the invention, the vibration element or actuator may be disposed on top of the light shielding layer and may be disposed on top of an opening formed in the light shielding layer.

According to embodiments of the invention, an adhesive layer is applied to secure a vibration element or actuator to a cover substrate, and the adhesive layer directly contacts the cover substrate. As a result, the light shielding layer may be prevented or reduced from being peeled or separated from the cover substrate due to vibration of the vibration element or actuator. Furthermore, since the adhesive layer directly contacts the cover substrate, the vibration element or actuator may be stably secured to the cover substrate.

According to embodiments of the invention, the adhesive layer may include a black dye or black pigment and has light blocking property. Since the adhesive layer has light blocking property, even when the adhesive layer is disposed in an opening, light incident through the opening may be blocked.

According to embodiments of the invention, a protective film is disposed on the adhesive layer, and the protective film has light blocking property and may be disposed to overlap the opening. By using such a protective film, light incident through the opening may be more effectively blocked.

Embodiments of the invention provide a technology that enables a vibration element or actuator to be stably attached and fixed to a display apparatus for haptic feedback.

Embodiments of the invention provide a technology that enables a stable attachment state to be maintained even when a vibration element or actuator is disposed on a light shielding layer of a cover substrate constituting a display apparatus.

Embodiments of the invention provide a vehicle including a display apparatus having a vibration element for haptic feedback.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
a cover substrate including a transmissive area and a blocking area;
a display panel overlapping the transmissive area;
a light shielding layer disposed on the blocking area;
at least one protective film disposed on the light shielding layer; and
a vibration element disposed on the at least one protective film,
wherein:
the light shielding layer includes at least one opening; and
each of the at least one protective film and the vibration element overlaps the at least one opening.

2. The display apparatus of claim 1, wherein a part of the cover substrate is exposed from the light shielding layer by the at least one opening.

3. The display apparatus of claim 1, further comprising a first adhesive layer between the light shielding layer and the at least one protective film,
wherein the first adhesive layer contacts the at least one protective film, and contacts the cover substrate in the at least one opening.

4. The display apparatus of claim 3, wherein the first adhesive layer has light blocking property.

5. The display apparatus of claim 3, wherein the first adhesive layer has an optical density of 1.5 or more.

6. The display apparatus of claim 1, wherein the at least one protective film has light blocking property.

7. The display apparatus of claim 1, further comprising a second adhesive layer disposed between the at least one protective film and the vibration element.

8. The display apparatus of claim 1, wherein:
the light shielding layer has two or more openings of the at least one opening; and
one protective film of the at least one protective film is disposed on the two or more openings.

9. The display apparatus of claim 1, wherein a plurality of the vibration elements are disposed on one protective film of the at least one protective film.

10. The display apparatus of claim 1, wherein a plurality of the vibration elements are disposed on one opening of the at least one opening.

11. The display apparatus of claim 3, further comprising a sealing material contacting the first adhesive layer and the at least one protective film.

12. The display apparatus of claim 1, further comprising a light shielding film disposed on the vibration element.

13. The display apparatus of claim 1, further comprising a touch unit arranged between the cover substrate and the display panel.

14. The display apparatus of claim 13, further comprising:
a touch sensing unit electrically connected to the touch unit; and
a vibration driving unit electrically connected to the touch sensing unit,
wherein:
the touch sensing unit is configured to sense a touch applied to the touch unit to generate a touch sensing signal; and
the vibration driving unit is configured to generate a vibration driving signal based on the touch sensing signal and to provide the vibration driving signal to the vibration element.

15. The display apparatus of claim 1, further comprising a fixing member for fixing the vibration element.

16. A vehicle display apparatus comprising:
a cover substrate including a transmissive area and a blocking area;
a display panel overlapping the transmissive area;
a light shielding layer disposed on the blocking area;
a protective film disposed on the light shielding layer; and
a vibration element disposed on the protective film,
wherein:
the light shielding layer includes an opening; and
each of the protective film and the vibration element overlaps the opening.

17. The vehicle display apparatus of claim 16, wherein the display panel, the light shielding layer, the protective film, and the vibration element are embedded in one of components of a vehicle.

18. The vehicle display apparatus of claim 16, further comprising a first adhesive layer disposed between the light shielding layer and the protective film,
wherein the first adhesive layer contacts the protective film and contacts the cover substrate in the opening.

19. The vehicle display apparatus of claim 16, further comprising a second adhesive layer disposed between the protective film and the vibration element.

20. The vehicle display apparatus of claim 16, further comprising a touch unit arranged between the cover substrate and the display panel.
